(19) United States
(12) Patent Application Publication
(10) Pub. No.: US 2003/0193826 A1
(43) Pub. Date: Oct. 16, 2003

(54) Reusable sold-state one-time programmable read only memory

(76) Inventors: Ching-Hsiang Hsu, Hsin-Chu City (TW); Kan-Chuan Huang, Tao-Yuan Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 10/063,303

(22) Filed: Apr. 10, 2002

(51) Int. Cl. G11C 17/00; G11C 16/04

(52) U.S. Cl. 365/185.05; 365/94

(57) ABSTRACT

A reusable non-volatile memory (NVM) includes a one-time programmable read only memory (OTPROM), a transparent cover formed above the NVM, and an opaque layer removably disposed on the transparent cover. The opaque layer can reflect light, and can be removed from the transparent cover for allowing light to shine onto the OTPROM so as to erase data stored in the OTPROM. During normal operation of the reusable NVM, the opaque layer is fixed on the transparent cover in order to prevent light from erasing the OTPROM. Conversely, the opaque layer can be removed from the transparent cover before the OTPROM is erased using ultraviolet light. Then, once the erasing procedure is completed, the opaque layer is once again fixed on the transparent cover.

### BACKGROUND OF INVENTION

1. Field of the Invention

The present invention relates to a reusable non-volatile memory, and more specifically, to a reusable one-time programmable read only memory for storing digital data.

2. Description of the Prior Art

As the consumer electronics market continues to grow, an increasing number of electronic products are utilizing non-volatile memory for storing digital information. Currently, products such as digital still cameras, personal digital assistants, digital picture frames, and cellular phones typically make use of flash memory to store digital information. Flash memory provides a means for the electronic product to store information in a non-volatile manner. For example, a digital still camera can use flash memory as digital film for storing digital images taken by the camera. The main advantage of flash memory is its reusability. A flash memory card can be written to and erased a large number of times. However, flash memory is also expensive to produce. Due to a complicated structure and manufacturing process, flash memory is more expensive to manufacture than other types of memory.

In addition to flash memory, a non-reusable non-volatile memory (NVM) that uses one-time programmable read only memory (OTPROM) can also be used to store digital data. Fortunately, OTPROM is simpler to manufacture than flash memory, and is therefore much less expensive. Please refer to FIG. 1. FIG. 1 is a cross-sectional diagram of a non-reusable NVM 10 according to the prior art. A control circuit 14 is formed on a printed circuit board (PCB) 12 for controlling operation of the non-reusable NVM 10. Likewise, an OTPROM 16 is formed on the PCB 12 for storing digital data. An opaque cover 18 is then formed on the PCB 12 to protect the OTPROM 16 from ultraviolet light that could erase or corrupt the data stored on the OTPROM 16. However, since the non-reusable NVM 10 contains an opaque cover 18 formed on it, the non-reusable NVM 10 cannot be erased for reuse. As a result, once a user fills up the OTPROM 16 of the non-reusable NVM 10 with data, a new non-reusable NVM 10 must be used in order to hold additional data. Thus, an inexpensive price of each non-reusable NVM 10 unit is offset by the inconvenience and expense of non-reusability.

### SUMMARY OF INVENTION

It is therefore a primary objective of the claimed invention to provide a reusable non-volatile memory (NVM) that includes a one-time programmable read only memory (OTPROM) to solve the above-mentioned problems.

According to the claimed invention, a reusable NVM includes an OTPROM, a transparent cover formed above the NVM, and an opaque layer removably disposed on the transparent cover. The opaque layer is capable of reflecting light, and is capable of being removed from the transparent cover for allowing light to shine onto the OTPROM so as to erase data stored in the OTPROM.

It is an advantage of the claimed invention that the reusable NVM contains the removable opaque layer for allowing the reusable NVM to be easily erased for reuse. During normal operation of the reusable NVM, the opaque layer is fixed on the transparent cover in order to prevent light from erasing the OTPROM. Conversely, the opaque layer can be removed from the transparent cover before the OTPROM is erased using ultraviolet light. Then, once the erasing procedure is completed, the opaque layer is once again fixed on the transparent cover.

These and other objectives of the claimed invention will no doubt become obvious to those of ordinary skill in the art after reading the following detailed description of the preferred embodiment, which is illustrated in the various figures and drawings.

### BRIEF DESCRIPTION OF DRAWINGS

FIG. 1 is a cross-sectional diagram of a non-reusable non-volatile memory (NVM) according to the prior art.

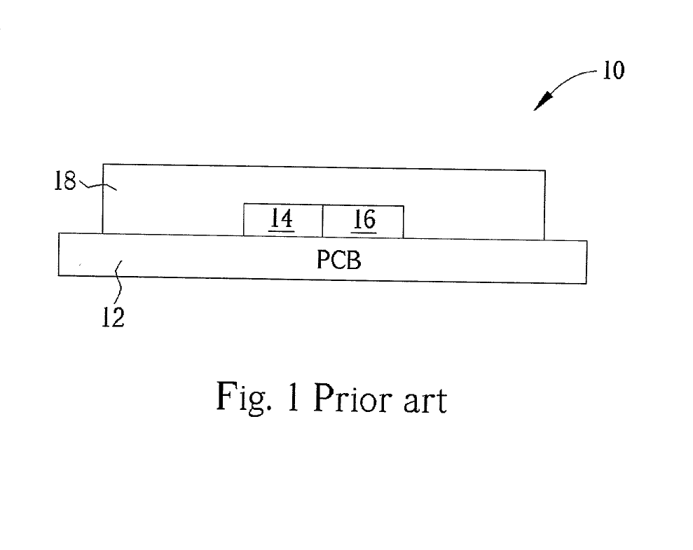

FIG. 2 is a cross-sectional diagram of a reusable NVM according to the present invention.

FIG. 3 is a functional block diagram of the reusable NVM shown in FIG. 2.

FIG. 4 is a perspective diagram of a card eraser used in conjunction with the reusable NVM.

### DETAILED DESCRIPTION

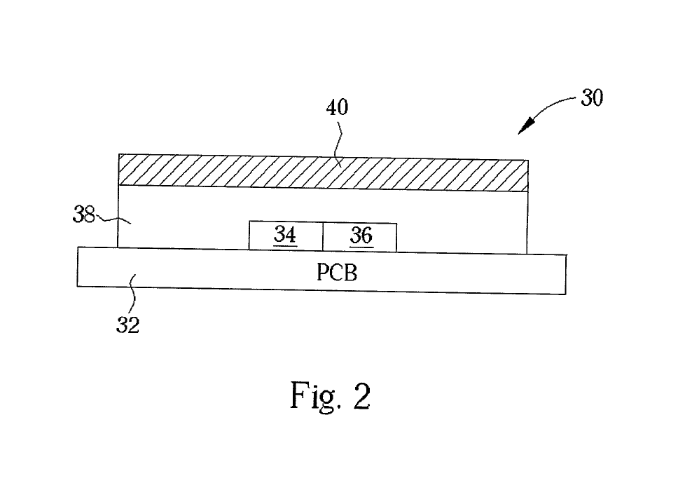

Please refer to FIG. 2. FIG. 2 is a cross-sectional diagram of a reusable non-volatile memory (NVM) 30 according to the present invention. A control circuit 34 is formed on a printed circuit board (PCB) 32 for controlling operation of the reusable NVM 30. A solid-state one-time programmable read only memory (OTPROM) 36 is also formed on the PCB 32 for storing digital data of the reusable NVM 30. To protect the control circuit 34 and the OTPROM 36 from outside debris, a protective transparent cover 38 is formed on the PCB 32.

When ultraviolet (UV) light shines on the OTPROM 36, the contents of the OTPROM 36 can be erased. To control exposure of the OTPROM 36 to UV light, an opaque sticker 40 is removably disposed on the transparent cover 38. The reusable NVM 30 contains the opaque sticker 40 for allowing the reusable NVM 30 to be easily erased for reuse. During normal operation of the reusable NVM 30, the opaque sticker 40 is fixed on the transparent cover 38 in order to prevent light from erasing the OTPROM 36. Conversely, the opaque sticker 40 can be removed from the transparent cover 38 before the OTPROM 36 is erased using ultraviolet light. Then, once the erasing procedure is completed, the opaque sticker 40 is once again fixed on the transparent cover 38. In this way, the user of the reusable NVM 30 can precisely control erasing operations of the OTPROM 36.

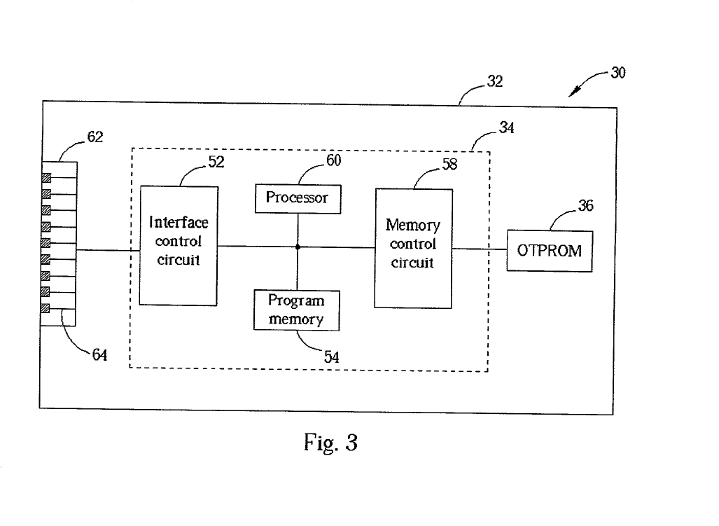

For a closer look at reusable NVM 30, please refer to FIG. 3. FIG. 3 is a functional block diagram of the reusable NVM 30 shown in FIG. 2. In addition to the control circuit 34 and the OTPROM 36, an interface 62 is also formed on the PCB 32.

The reusable NVM 30 can be connected to an electronic device for storing digital data transmitted from the electronic device. The reusable NVM 30 comprises an interface control circuit 52 for controlling interface between the electronic device and the reusable NVM 30, a program memory 54 for storing program codes of the reusable NVM 30, and the OTPROM 36 for storing digital data transmitted from the electronic device. The reusable NVM 30 also comprises a memory control circuit 58 electrically connected between the interface control circuit 52 and the OTPROM 36 for storing the digital data transmitted from the interface control circuit 52 into the OTPROM 36. A processor 60 is used to control operations of the reusable NVM 30. For receiving digital signals transmitted from the electronic device, the reusable NVM 30 uses the interface 62 which is compatible with the electronic device. The interface 62 has a plurality of gold fingers 64 electrically connected to the interface control circuit 52 for receiving the electrical signals from any electronic device that uses a same interface. For example, the reusable NVM 30 can be used in a range of memory cards such as a Compact Flash Card, Smart Media Card, Multi Media Card, Secure Digital Card, or Memory Stick.

To better illustrate the use of the reusable NVM 30, brief descriptions will be given of how to write, read, and erase data on the reusable NVM 30. First of all, the opaque sticker 40 is fixed on the transparent cover 38. After that, the reusable NVM 30 is inserted into a host device, such as a digital camera, which supports the same electrical interface as the reusable NVM 30. The host device will then write digital data to the OTPROM 36 of the reusable NVM 30.

Next, the reusable NVM 30 can be inserted into a device such as a PDA, notebook computer, PC, or audio player in order to read the information stored on the reusable NVM 30. For example, if the reusable NVM 30 contains audio files such as MP3s, the audio files can be played on an audio player. On the other hand, if the reusable NVM 30 contains digital images, a PC, notebook, or PDA can be used to view the images. Likewise, the reusable NVM 30 could be inserted into a photo printer in order to directly print out the digital images stored on the reusable NVM 30.

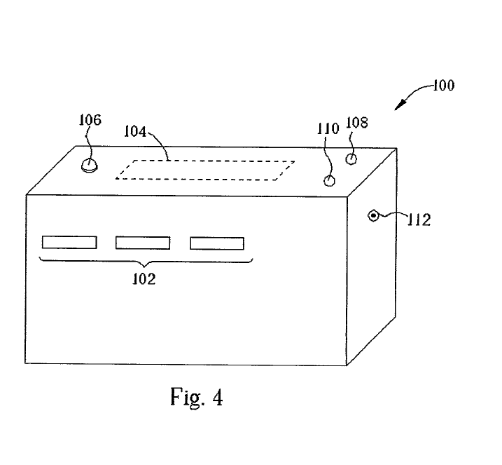

Finally, once the contents of the OTPROM 36 have been read, the opaque sticker 40 can be removed from the transparent cover 38 and the reusable NVM 30 can be erased. Please refer to FIG. 4. FIG. 4 is a perspective diagram of a card eraser 100 used in conjunction with the reusable NVM 30. The card eraser 100 contains a plurality of card slots 102 that can accommodate memory cards of different standards such as a Compact Flash Card, Smart Media Card, Multi Media Card, Secure Digital Card, or Memory Stick. The reusable NVM 30 is inserted into one of the card slots 102 for erasure. DC power is then supplied to the card eraser 100 through a DC input jack 112. To start the erasing procedure, a start button 106 is pressed. Once started, a UV light 104 in the card eraser 100 is turned on, and the contents of the OTPROM 36 on the reusable NVM 30 are gradually erased by the UV light 104. Two status indicator lights 108 and 110 are provided for users to monitor status of the card eraser 100. For example, an erasing in progress indicator 108 is turned on to indicate that the erasing procedure is still underway. Then, once the erasing procedure is completed, the erasing in progress indicator 108 is turned off and an erase completed indicator 110 is turned on. The preferred colors for these indicators is a red light for the erasing in progress indicator 108 and a green light for the erase completed indicator 110. At last, the erasing procedure for the reusable NVM 30 is completed. At that time, the opaque sticker 40 should once again be fixed on the transparent cover 38 and the reusable NVM 30 can be used again.

Compared to the prior art, the present invention reusable NVM 30 uses the removable opaque layer 40 for allowing the reusable NVM to be easily erased for reuse. Thus, the reusable NVM 30 according to the present invention has the reusability of flash memory while at the same time using the inexpensive structure of OTPROM.

Those skilled in the art will readily observe that numerous modifications and alterations of the device may be made while retaining the teachings of the invention. Accordingly, the above disclosure should be construed as limited only by the metes and bounds of the appended claims. claims

What is claimed is:

1. A reusable non-volatile memory (NVM) comprising:
a one-time programmable read only memory (OTPROM);
a transparent cover formed above the NVM; and
an opaque layer removably disposed on the transparent cover;
wherein the opaque layer is capable of reflecting light, and is capable of being removed from the transparent cover for allowing light to shine onto the OTPROM so as to erase data stored in the OTPROM.

2. The NVM of claim 1 being formed on a printed circuit board.

3. The NVM of claim 2 being electrically connected to a memory control circuit for controlling data transmitted to the NVM.

4. The NVM of claim 3 wherein the memory control circuit is electrically connected to an interface control circuit for controlling interface between the memory control circuit and an external electronic device.

5. The NVM of claim 4 wherein the interface control circuit is electrically connected to an interface such as Compact Flash Card, Smart Media Card, Multi Media Card, Secure Digital Card, or Memory Stick.

6. The NVM of claim 4 wherein the interface control circuit supports interface standards including Compact Flash Card, Smart Media Card, Multi Media Card, Secure Digital Card, and Memory Stick.

7. The NVM of claim 4 wherein a processor is electrically connected to both the memory control circuit and the interface control circuit for processing programs and data.

8. The NVM of claim 7 wherein a program memory is electrically connected to the processor, the memory control circuit, and the interface control circuit for providing system code to the processor.

9. The NVM of claim 1 wherein the light used to erase the data of the OTPROM is ultraviolet (UV) light.
